(19) United States
(12) Patent Application Publication
(10) Pub. No.: US 2016/0270187 A1
(43) Pub. Date: Sep. 15, 2016

(54) LIGHT-EMITTING DEVICE, DEVICE AND METHOD FOR ADJUSTING THE LIGHT EMISSION OF A LIGHT-EMITTING DIODE COMPRISING PHOSPHORUS

(71) Applicant: COMMISSARIAT À L'ÉNERGIE ATOMIQUE ET AUX ÉNERGIES ALTERNATIVES, Paris (FR)

(72) Inventors: Ivan-Christophe ROBIN, Grenoble (FR); Alexei TCHELNOKOV, Meyland (FR); Bruno MOUREY, Coublevie (FR)

(73) Assignee: COMMISSARIAT A L'ENERGIE ATOMIQUE ET AUX ENERGIES ALTERNATIVES, Paris (FR)

(21) Appl. No.: 15/031,881

(22) PCT Filed: Oct. 24, 2014
(86) PCT No.: PCT/EP2014/072899

§ 371 Date: Apr. 25, 2016

(30) Foreign Application Priority Data
Oct. 25, 2013 (FR) 13 60417

(51) Int. Cl. H05B 37/02; H01L 31/16; H01L 33/56; H01L 33/06; H01L 33/32; H01L 33/02; H01L 33/42; H05B 33/08; H01L 33/50

(52) U.S. Cl. CPC H05B 37/0227; H05B 33/0851; H05B 33/0815; H01L 31/162; H01L 33/56; H01L 33/502; H01L 33/32; H01L 33/025; H01L 33/42; H01L 33/06

(57) ABSTRACT

A light-emitting device including: a light-emitting diode including an active zone coupled to phosphorus; a detector of a spectrum and of an intensity of a light to be emitted by the light-emitting diode; a switched-mode electric power supply configured to electrically power the light-emitting diode with a periodic signal with a duty cycle α such that αε]0;1]; a controller of the switched-mode electric power supply which can alter at least one of a peak value, a period, and the duty cycle α of the periodic signal according to the spectrum and intensity of the light to be detected and according to target values of the spectrum and of the intensity.

### TECHNICAL FIELD ET PRIOR ART

The invention relates to the field of light-emitting diodes (named LEDs) comprising active zones coupled to phosphorus, and in particular that of light-emitting devices comprising one or several LEDs (bulbs, screens, projectors, display walls, etc.). The invention also relates to a device and a method for adjusting the light emission characteristics of a LED comprising an active zone coupled to phosphorus, able to be used in particular to determine the electrical power supply parameters of the LED making it possible to obtain a light emission according to a desired light spectrum and intensity.

Some LEDs, such as LEDs intended to emit a white light, each comprise an active zone coupled to phosphorus that converts a portion of a blue light emitted by the active zones actives of the LEDs into a yellow light, which makes it possible to have in the end an emission of white light. During the making of these LEDs, the latter are sorted at production output in order to retain only those of which the emission wavelength at the output of the active zones corresponds precisely to the wavelength sought, i.e. the optimal wavelength to excite the phosphorus.

However, the value of the wavelength emitted by the LEDs depends on several parameters of LEDs, in particular the composition of the materials of the quantum wells within the active zones of the LEDs and the thickness of these quantum wells.

For the production of these LEDs, a large-size substrate (100 mm, 150 mm, or 200 mm in diameter) is used to grow various semiconductor materials (for example via epitaxy), these stacks of materials forming the active zones of the LEDs which comprise in particular the quantum wells corresponding to the emitting layers of the LEDs.

The substrate is then cut into very small rectangles (dies), forming individual chips comprising one or several LEDs. Electrical contacts are then made and phosphorus is added in the form of a coating on the emitting portion of the LEDs, i.e. on the active zones of the LEDs.

Slight variations in the thickness of the quantum wells and/or in the composition of the materials of the quantum wells, due to the steps of manufacturing implemented, have a significant influence on the emission spectrum obtained as output from the LEDs. As such, for a LED comprising several quantum wells comprising InGaN and emitting normally at a wavelength of about 420 nm (at the output of the active zone and before the passage of this light through the phosphorus), a modification of about 1% in the indium composition in the semiconductor of the quantum wells, i.e. the proportion of indium in the InGaN, modifies by about 5 nm the wavelength emitted by the LED. Likewise, a modification of about 0.5 nm in the thickness of one of the quantum wells of InGaN of a nominal thickness of about 2.5 nm of such a LED results in an offset in the emission wavelength of about 10 nm. However, the values of these two parameters (thickness and composition of the materials of the quantum wells) can vary substantially from one LED to another at the output of production, in particular dues to the growth processes implemented for their manufacture, which can create substantial variations in the colour emitted in the end by the LEDs. Instead of obtaining the emission of a white light, it is possible to have as output from these LEDs a spectrum tending towards blue or towards yellow.

In addition, such a LED can have its emission peak, i.e. the value of the wavelength for which the light emission is maximum within the spectrum of the light emitted, which varies according to the injection power, i.e. the power with which these LEDs are supplied, as well as the temperature, with these parameters affecting the manner with which the phosphorus of the LEDs is excited. As such, the spectrum of the light emitted by such a LED can also vary according to the environment wherein this LED operates.

### DISCLOSURE OF THE INVENTION

A purpose of this invention is to propose a light-emitting device comprising at least one light-emitting diode of which one active zone is coupled to phosphorus and which makes it possible to be free from and offset any variations in the spectrum of the light emitted by the light-emitting diode, for example due to structural variations of the active zone of the light-emitting diode and/or variations in the operating conditions of the light-emitting diode.

For this, this invention proposes a light-emitting device comprising at least:
a light-emitting diode comprising an active zone coupled to phosphorus,
a device for detecting a spectrum and an intensity of a light intended to be emitted by the light-emitting diode,
a switched-mode electric power supply able to electrically power the light-emitting diode with a periodic signal of which a duty cycle α is such that αε]0;1],
a device for controlling the switched-mode electric power supply which can alter a peak value and/or a period and/or the duty cycle α of the periodic signal according to spectrum and the intensity of the light intended to be detected and according to the target values of the spectrum and of the intensity.

Such a light-emitting device therefore makes it possible to offset any variations in the spectrum of light emitted by the light-emitting diode, for example due to variations in the operating conditions of the light-emitting diode (injection power, temperature, etc.) and/or variations in the structure of the active zone of the light-emitting diode, by adjusting the electric power supply parameters of the light-emitting diode. Indeed, if the light-emitting diode emits, when it is supplied with a standard periodic signal, a light of which the spectrum does not correspond to the target value sought (for example a spectrum corresponding to that of a relatively homogeneous white light), this difference between the spectrum of light emitted and the target value sought is detected by the device for detecting of the light-emitting device. The device for controlling the light-emitting device then adapts the period and/or the duty cycle of the periodic signal that powers the light-emitting diode, as such modifying the relationship between the durations of lighting and of extinction of the light-emitting diode (corresponding respectively to the portion of the period during which the value of the power signal is equal to its peak value and to the portion of the period during which the value of the power signal is zero) and the duration of the response time of the phosphorus, which makes it possible to correct the light spectrum emitted by the light-emitting diode and to offset this spectrum towards the target value sought.

This correction in the spectrum of the light emitted by the light-emitting diode is based on the fact that the phosphorus coupled to the light-emitting diode has a certain response time before completely carrying out the function of converting into wavelength of the light received.

It is therefore possible to vary the average luminescence of the phosphorus, and therefore the wavelength of the light emitted by the phosphorus, by varying the duration during which the phosphorus is excited continuously, with this duration corresponding to that during which the value of the power signal is equal to its peak value during one period.

Such a correction of the spectrum of the light emitted by the light-emitting diode may be carried out when the power of the light emitted by the active zone of the light-emitting diode is not sufficient to saturate the phosphorus during the duration of lighting of the light-emitting diode (with the value of this level of power being according to the type of light-emitting diode used as well as the nature of the phosphorus used). The period of the power signal is in this case relatively short and is for example of the same order of magnitude as the response time of the phosphorus.

As long as the phosphorus is not saturated, its light emission is proportional to its excitation, i.e. such that the Intensity(emission)=α.Intensity(excitation), and the light intensity re-emitted by the phosphorus increases in proportion to the increase in excitation. As such, when the phosphorus is not saturated, if the intensity of excitation is multiplied by a factor x, then the light intensity re-emitted by the phosphorus is also multiplied by the factor x.

Starting from a particular value of excitation power which depends on the nature of the phosphorus and on the excitation wavelength, the proportion of the light intensity re-emitted by the phosphorus with respect to the excitation intensity decreases. In this case, if the excitation intensity is multiplied by a factor x>1, the light intensity re-emitted by the phosphorus is then multiplied by a factor y such that y<x. The phosphorus is completely saturated when an increase in the excitation intensity no longer results in an increase in the light intensity re-emitted by the phosphorus.

Such a modification of the duty cycle of the periodic signal powering the light-emitting diode can result in a change in the intensity of the light emitted by the light-emitting diode. Indeed, by modifying these parameters, the average value of the intensity or of the voltage electrically powering the light-emitting diode can also vary.

However, the intensity of the light emitted by the light-emitting diode is linked to the average value of the signal electrically powering the light-emitting diode. In this case, so that the correction of the spectrum carried out does not affect the light intensity of the light-emitting diode, the peak value of the electric power signal of the light-emitting diode can be modified in order to offset the increase or the decrease in the light intensity generated by the correction of the light spectrum of the light-emitting diode. In addition, the value of the duty cycle can also be chosen so that the value of the intensity of the light emitted by the light-emitting diode corresponds to the target value sought while still carrying out the correction sought for the spectrum of the light emitted by the light-emitting diode.

Another advantageous way to correct the spectrum of the light emitted by the light-emitting diode is to adjust the saturation of the phosphorus according to the intensity of the light emitted by the active zone of the light-emitting diode. Such a correction can be used when the power of the light emitted by the active zone of the light-emitting diode is sufficient to saturate the phosphorus during the duration of lighting of the light-emitting diode. For example, in the case of a light-emitting diode of which the active zone emits a light with a power sufficient to saturate the phosphorus, the spectrum of the light emitted by the light-emitting diode can be changed by adjusting the state of saturation of the phosphorus with respect to the intensity of the light emitted by the active zone of the light-emitting diode.

As such, for a phosphorus emitting a light of a first colour (for example the yellow colour) and when the spectrum of the light emitted by the light-emitting diode tends towards this first colour, it is possible to offset this spectrum towards a second colour (for example blue) corresponding to that of the light emitted by the active zone of the light-emitting diode by increasing the peak value of the power signal of the light-emitting diode.

Due to the fact that the phosphorus is in a state of saturation, the latter then has difficulty in emitting more yellow light, and the blue component (emitted from the active zone) with respect to the yellow component (emitted from the phosphorus) of the spectrum becomes more substantial, as such correcting the spectrum of the light emitted from the light-emitting diode, corresponding for example to that of a white light. So that this increase in the peak value of the power signal has little or no effect on the average light power emitted by the light-emitting diode, it is also possible to decrease the value of the duty cycle and/or the period of the power signal in such a way that the light-emitting diode is lit on the average longer.

Inversely, still with a phosphorus emitting a first colour (for example yellow) and an active zone emitting a second colour (for example blue) that is different from the first colour, it is possible to offset the light emission spectrum of the light-emitting diode towards the first colour by reducing the peak value of the power signal, as such increasing the proportion of the yellow light emitted by the phosphorus in the global light spectrum of the light-emitting diode, and to increase the value of the duty cycle and/or the period of the power signal so that the light-emitting diode is lit on average longer.

In any case, the entirety of the global light intensity emitted by the light-emitting diode will be the same, but the spectrum of the light emitted by the light-emitting diode will be modified.

The light-emitting diode, the device for detecting the spectrum and the intensity of the light intended to be emitted, the device for controlling and the switched-mode electric power supply can thus form together a feedback loop making it possible to carry out a control and an adjusting of the spectrum and of the intensity of the light emitted by the light-emitting diode of such a light-emitting device.

The period and/or the duty cycle of the periodic electric power signal of the light-emitting diode may be used as variables for adjusting the spectrum of the light emitted by the light-emitting diode, and the duty cycle and/or the peak value of the periodic electric power signal of the light-emitting diode can be used as variables for adjusting the intensity of the light emitted by the light-emitting diode. Such a case may correspond to the case where the power of the light emitted by the active zone of the light-emitting diode is not sufficient to saturate the phosphorus during the duration of lighting of the light-emitting diode.

In another advantageous case, the peak value of the periodic electric power signal of the light-emitting diode may be used as a variable for adjusting the spectrum of the light emitted by the light-emitting diode, and the duty cycle and/or the period of the periodic electric power signal of the light-emitting diode may be used as variables for adjusting the intensity of the light emitted by the light-emitting diode. Such a case may correspond to the case where the power of the light emitted by the active zone of the light-emitting diode is sufficient to saturate the phosphorus during the duration of lighting of the light-emitting diode.

When the phosphorus is not in a state of saturation, the period of the periodic electric power signal of the light-emitting diode may be used as a variable for adjusting the global light intensity obtained. Periods that are less than the response time of the phosphorus can in this case be used. The effect of the adjustment is in this case much weaker than when the phosphorus saturates.

Such a light-emitting device also makes it possible to offset the effects of the ageing of the light-emitting diode. Indeed, because the wavelength emitted by a light-emitting diode varies over time and its luminosity decreases over time, such a light-emitting device makes it possible to offset these effects due to the ageing of the light-emitting diode and therefore prolong its length of operation and its length of life.

With such light-emitting devices, it is therefore possible to homogenize the emission spectra of light-emitting diodes that have for example structural variations due to the steps in their manufacture, without having to sort and eliminate a large portion of the chips at the production output. This makes it possible to reduce “binning”, i.e. the sorting of chips after epitaxy and hybridisation due to their dispersion in emission wavelength.

The spectrum of the light emitted by the light-emitting diode corresponds to all of the wavelengths of the light emitted by the light-emitting diode.

Such a light-emitting device may correspond for example to a bulb with a light-emitting diode or diodes in which the device for detecting the spectrum and the intensity of the light intended to be emitted, the device for controlling and the switched-mode electric power supply are made in the form of electronics integrated into the bulb. This light-emitting device can also correspond to a screen, a projector or a display wall comprising several light-emitting diodes.

The active zone of the light-emitting diode may comprise one or several emitting layers each able to form a quantum well.

The emitting layer or layers may comprise InGaN.

The light-emitting diode may further comprise at least one n-doped semiconductor layer and at least one p-doped semiconductor layer between which are located the active zone. These doped semiconductor layers form the p-n junction of the light-emitting diode, with the active zone of the light-emitting diode comprising in particular the emitting layer or layers being arranged between these doped semiconductor layers.

The device for detecting the spectrum and the intensity of the light intended to be emitted by the light-emitting diode may comprise several photodiodes optically coupled to the light-emitting diode and electrically connected to the device for controlling the switched-mode electric power supply. It is possible to have for example three photodiodes coupled to coloured filters so that each photodiode is sensitive to one of the colours blue, green or red, which makes it possible to determine the emission spectrum of the light-emitting diode. The intensity of the light emitted may be obtained using the sum of the photo-currents outputted by the three photodiodes.

The periodic signal may be a square signal. This square signal can also be named a rectangular signal, as the value of its duty cycle α is able to vary and is not necessarily equal to 0.5.

The frequency of the periodic signal may be between about 20 Hz and 1 MHz. In this way, the light emitted by the light-emitting device and observed by a person is perceives as being constant by this person due to retinal persistence.

When the phosphorus is in a state of saturation, the frequency of the periodic signal is of little importance. Indeed, in such a state of saturation, the peak value of the periodic signal changes the spectrum such that the higher this peak value is, the higher the light emission from the active zone of the diode, for example of blue colour, is in the global spectrum, and the lower this peak value is, the more the emission of the phosphorus (for example of yellow colour) is dominant with respect to the light emission of the active zone of the light-emitting diode in the global spectrum obtained. In addition, the luminosity obtained varies according to the value of the duty cycle of the periodic signal. However, when the phosphorus is not saturated, the frequency of the periodic signal can be used as a variable for adjusting the spectrum of the light emitted, with this frequency able in this case to be chosen greater than 1/τ, with τ corresponding to the response time of the phosphorus.

The invention also relates to a device for adjusting a spectrum and an intensity of light intended to be emitted by a light-emitting diode comprising an active zone coupled to the phosphorus, with the device for adjusting comprising at least:
a device for detecting the spectrum and the intensity of the light intended to be emitted by the light-emitting diode,
a switched-mode electric power supply able to electrically power the light-emitting diode with a periodic signal of which a duty cycle α is such that αε]0;1],
a device for controlling the switched-mode electric power supply which can alter a peak value and/or a period and/or the duty cycle α of the periodic signal according to the values of the spectrum and of the intensity of the light intended to be detected and according to the target values of the spectrum and of the intensity.

Such a device for adjusting can for example be used to test light-emitting diodes in order to determine, for each one of these light-emitting diodes, the values of the period and/or of the duty cycle and/or of the peak value of the electric power signal making it possible to obtain an emission of light for which the spectrum and the intensity correspond to the target values sought.

The invention also relates to a method for adjusting a spectrum and an intensity of light intended to be emitted by a light-emitting diode comprising an active zone coupled to the phosphorus, with the method comprising at least the following steps:
detecting the value of the spectrum and of the intensity of the light emitted by the light-emitting diode,
adjusting a period and/or a duty cycle α such as αε]0;1] and/or a peak value of a periodic signal electrically powering the light-emitting diode, according to the spectrum and the intensity of the light detected and according to the target values of the spectrum and of the intensity,

with these steps being repeated iteratively until the spectrum and the intensity of the light detected correspond to the target values of the spectrum and of the intensity.

When a light emitted by the active zone is of a power less than that making it possible to saturate the phosphorus, the step of adjusting may carry out an adjustment of the value of the period and/or of the value of the duty cycle of the period signal according to the spectrum of the light detected and according to the target value of the spectrum, and can carry out an adjustment of the value of the duty cycle and/or of the peak value of the periodic signal according to the intensity of the light detected and according to the target value of the intensity.

Alternatively, when a light emitted by the active zone is of a power greater than or equal to that making it possible to saturate the phosphorus, the step of adjusting may carry out an adjustment of the peak value of the period signal according to the spectrum of the light detected and according to the target value of the spectrum, and may carry out an adjustment of the value of the duty cycle and/or of the period of the periodic signal according to the intensity of the light detected and according to the target value of the intensity.

### BRIEF DESCRIPTION OF THE DRAWINGS

This invention shall be better understood when reading the description of embodiments provided solely for the purposes of information and in no way limiting in reference to the annexed drawings wherein:

FIG. 1 diagrammatically shows a light-emitting device, subject-matter of this invention, according to a particular embodiment;

FIG. 2 diagrammatically shows an electrical signal electrically powering a LED of the light-emitting device, subject-matter of this invention;

FIG. 3 diagrammatically shows a first embodiment of a LED of the light-emitting device, subject-matter of this invention;

FIG. 4 shows the luminescence of the phosphorus of the LED obtained with a first period signal electrically powering the LED and of which a duration of lighting, during each period, is greater than a response time of the phosphorus coupled to the active zone of the LED;

FIG. 5 shows the luminescence of the phosphorus of the LED obtained with a second period signal electrically powering the LED and of which a duration of lighting, during each period, is less than a response time of the phosphorus coupled to the active zone of the LED;

FIGS. 6A to 6C diagrammatically show different emission spectra of the light-emitting device, subject-matter of this invention obtained with different power signals when the phosphorus is in a state of saturation.

Identical, similar or equivalent parts of the various figures described hereinafter bear the same numerical references in such a way as to facilitate passing from one figure to another.

The various parts shown in the figures are not necessarily shown according to a uniform scale, in order to make the figures more legible.

The various possibilities (alternatives and embodiments) must be understood as not being exclusive with respect to one another and can be combined together.

### DETAILED DISCLOSURE OF PARTICULAR EMBODIMENTS

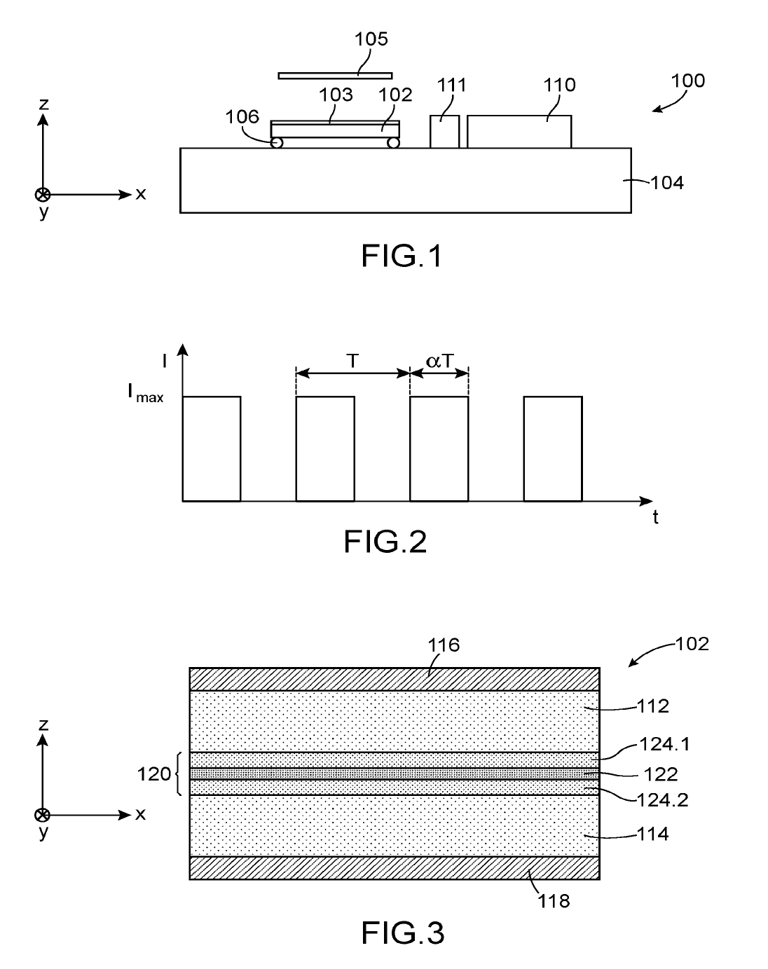

Reference is first made to FIG. 1 which diagrammatically shows a light-emitting device 100 according to a particular embodiment.

The light-emitting device 100 comprises a LED 102 which here is intended to carry out a light emission of white colour. This light emission of white colour is obtained thanks to an emitting structure of the LED 102, or active zone, able to emit a blue light and thanks to phosphorus 103 covering this emitting structure, with this phosphorus making it possible to convert a portion of the blue light emitted into a light of yellow colour. The addition of the light of yellow colour emitted by the phosphorus 103 and of the portion of the light of blue colour that passes through the phosphorus 103 without being converted into yellow light forms a light of white colour corresponding to the light emitted at the output of the LED 102. The LED 102 is mechanically and electrically coupled on a substrate 104, for example made of silicon, via beads of fusible material 106. Alternatively, the LED 102 could be made directly by growth on the substrate 104.

The phosphorus 103 has a longer response time than the time for lighting the emitting structure of the LED 102. The saturation of the phosphorus can be reached more or less easily according to the quantity of phosphorus deposited. The phosphorus 103 deposited on the emitting structure of the LED 102 may correspond to a phosphorus powder dispensed in silicone. If it is desired that the phosphorus 103 saturate for low excitation densities, i.e. a low light power emitted by the emitting structure of the LED 102, a low quantity of phosphorus is then deposited on this emitting structure. For this, it is possible to dilute this powder in the silicone and to deposit a small thickness of this mixture. Inversely, if it is desired that the phosphorus 103 saturate less easily, higher concentrations of phosphorus in the silicone are used and a greater thickness of this mixture is deposited onto the emitting structure of the LED 102. The phosphorus powder used to make the phosphorus 103 is for example of the type: YAG:Ce and/or Eu-doped CaSiAlON and/or M₂Si₅N₈ with M=Ca, Sr or Ba, Eu-doped. Any type of phosphorus of the nitride or oxynitride type can be used. It is also possible to use a phosphorus of the silicate type, or a red/orange phosphorus such as Eu-doped SrAlSi₄N₇.

The process of saturation of phosphorus are for example described in document “Eu²⁺—Mn²⁺ phosphor saturation in 5 mm light emitting diode lamps” by A. A. Setlur et al., Applied Physics Letters, Vol. 92, Issue 8, 2008, Pages 081104-081104-3, as well as in the document “Energy Transfer and Brightness Saturation in (Sr, Ca)2P₂O₇:Eu²⁺,Mn²⁺ Phosphor for UV-LED Lighting” by T.-G. Kim et al., Journal of the Electrochemical Society, 2009, Vol. 156, Issue 7, J203-J207.

The light-emitting device 100 comprises a detecting device 105 of a spectrum and an intensity of the light emitted by the LED 102, arranged facing the LED 102. The detecting device 105 may be transparent and/or be arranged facing a portion only of the LED 102 so as to disturb as least as possible the light emission carried out by the LED 102. It is also possible to use a semi-transparent blade that reflects only a small portion of the light emitted by the LED 102 in the detecting device, with such a blade being advantageously used when the detecting device 105 is not transparent. The detecting device 105 may be connected mechanically to the substrate 104.

The detecting device 105 comprises for example three photodiodes each covered by a coloured filter so that each one of these photodiodes is able to detect one of the colours red, green and clue of the light emitted by the LED 102, and that the detecting device 105 is able to determine as such the spectrum, i.e. all of the wavelengths, of the light emitted by the LED 102. In addition, the detecting device 105 also comprises calculating means (not shown in FIG. 1) coupled to the photodiodes and making it possible to calculate, using the electric signals outputted by the photodiodes (for example via the calculation of the sum of these signals), the intensity of the light emitted by the LED 102. Alternatively, the detecting of the spectrum of the light emitted by the LED 102 and the detecting of the intensity of the light emitted by the LED 102 could be carried out by two separate devices.

The light-emitting device 100 also comprises a switched-mode electric power supply 110 making it possible to electrically power the LED 102. This switched-mode power supply 110 outputs a voltage or a current in the form of a periodic signal, for example a square signal, of which a period T, a peak value Iₘₐₓ or Uₘₐₓ and a duty cycle α can be adjusted, with the duty cycle α being such that αε]0,1]. FIG. 2 shows an example of the periodic signal of the electrical supply of the LED 102, here a current in the form of a square signal.

These parameters of the electrical signal outputted by the switched-mode power supply 110 are controlled by a control device 111 receiving as input the detected values of the spectrum and of the intensity of the light emitted by the LED 102 and outputting a control signal sent to the switched-mode power supply 110 (alternatively, it is possible that the control device 111 and the switched-mode electric power supply 110 form a single element). These elements form a feedback loop such that the period T, the peak value Iₘₐₓ or Uₘₐₓ, and the duty cycle α of the signal outputted by the switched-mode power supply 110 are according to the difference between the detected values of the spectrum and of the intensity and the values of the spectrum and of the intensity desired for the light intended to be emitted by the LED 102. When the detecting of the spectrum and the detecting of the light intensity are carried out by two separate detecting devices, these two detecting devices may be coupled optically to the LED 102 and electrically connected to the control device 111 by forming two feedback loops.

A first embodiment of the LED 102 is diagrammatically shown in FIG. 3.

The LED 102 comprises a p-n junction formed by an n-doped semiconductor layer 112 and a p-doped semiconductor layer 114. The semiconductor of the layers 112 and 114 is for example GaN. The layer 112 is n-doped with a concentration of donors between about 10¹⁷ and 5.10¹⁹ donors/cm³. The layer 114 is p-doped with a concentration of acceptors between about 10¹⁷ and 5.10¹⁹ donors/cm³.

These two layers 112 and 114 each have for example a thickness (dimension according to the Z-axis shown in FIG. 3) between about 20 nm and 10 μm. A first transparent electrode 116 is arranged against the n-doped layer 112 and forms a cathode of the LED 102, and a second transparent electrode 118 is arranged against the p-doped layer 114 and forms an anode of the LED 102.

The LED 102 comprises, between the n-doped layer 112 and the p-doped layer 114, an active zone 120 comprising one or several emitting layers 122 comprising a semiconductor, here InGaN, forming one or several quantum wells of the LED 102. The thickness of the emitting layer 122 or of each one of the emitting layers 122 is for example equal to about 3 nm and more generally between about 0.5 nm and 10 nm. The active zone 120 also comprises at least two barrier layers 124.1 and 124.2 each comprising a semiconductor with a higher energy of the band gap than that of the emitting layer 122, for example GaN, between which the emitting layer 122 is arranged. The barriers layers 124.1 and 124.2 are preferably made with semiconductors of the same family than that used for making the emitting layer 122. The semiconductors used to make the LED 102 may all be of the family of nitrides, i.e. comprising nitrogen as a common element of column 15, or column VA, of the periodic table of elements. The gap of these semiconductors may be adjusted by varying the ratio of the atomic compositions of gallium and of indium in the layers: the barrier layers 124.1 and 124.2 may be made of GaN and the emitting layer 122 of InGaN.

The first barrier layer 124.1 is arranged between the n-doped layer 112 and the emitting layer 122, and the second barrier layer 124.2 is arranged between the p-doped layer 114 and the emitting layer 122. When the active zone 120 comprises several emitting layers 122, each one of these emitting layers 122 is arranged between and against two barrier layers 124.

The thickness of each one of the barrier layers 124.1 and 124.2 is for example between about 1 nm and 25 nm. All of the layers of the active zone 120 of the LED 102, i.e. the emitting layer or layers 122 and the barrier layers 124, comprise unintentionally doped materials (of a concentration in residual donors n_{nid} equal to about 10¹⁷ donors/cm³, or between about 10¹⁵ and 10¹⁸ donors/cm³).

The layers 112, 114, 116, 118, 122, 124.1 and 124.2 of the LED 102 form the emitting structure of the LED 102.

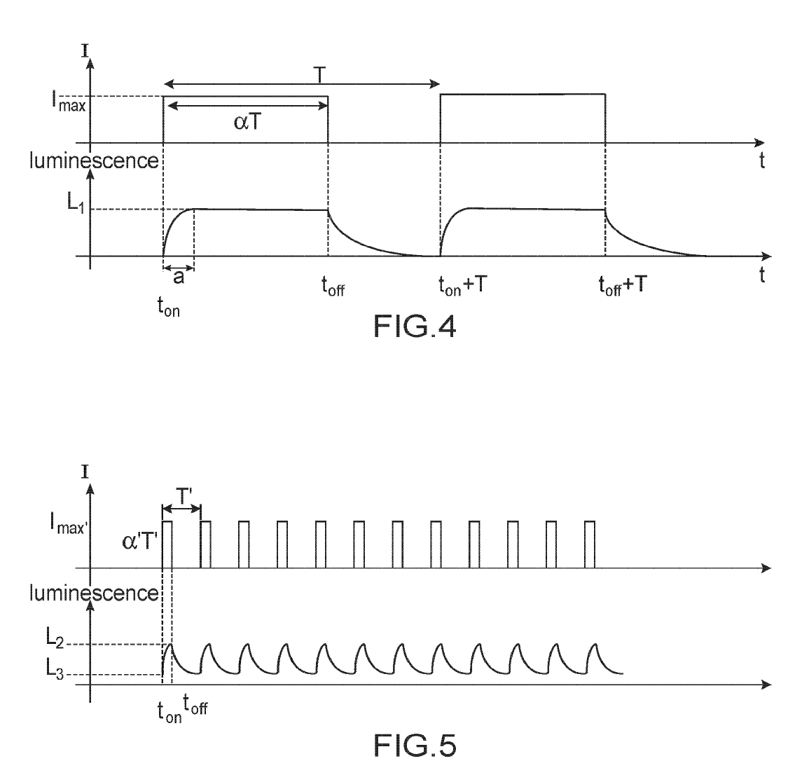

FIG. 4 shows the luminescence of the phosphorus 103 (bottom curve) obtained when the LED 102 is electrically powered by a first current corresponding to a square signal (top curve). The current powering the LED 102 has a peak value Imax, a period T and a duty cycle α. At an instant tₒₙ corresponding to the beginning of the period T, the square electric power signal of the LED 102 passes from the value 0 to the peak value Iₘₐₓ.

Light of the blue colour is then emitted from the active zone 120 of the LED 102 and excites the phosphorus 103. It can be seen in FIG. 4 that the luminescence of the phosphorus 103 then increases progressively during a duration named “a” until reaching a maximum value L₁, with this duration “a” corresponding to the response time of the phosphorus 103. This progressive increase in the luminescence of the phosphorus 103 reflects the progressive increase of the quantity of blue light converted by the phosphorus 103 into yellow light. As such, during this duration “a”, the spectrum of the light emitted by the LED 102 does not correspond to that of a white light, but to that of a light tending towards blue.

After this duration “a” and during the rest of the duration αT, i.e. the duration of lighting of the LED 102, during which the power current remains at the value Iₘₐₓ, the luminescence of the phosphorus 103 remains equal to L₁, and the conversion of the blue light into yellow light carried out by the phosphorus 103 is substantially constant. The spectrum of the light obtained at the output of the LED 102 then corresponds theoretically to that of a white light. At an instant t_{off} corresponding to the end of the duration αT, the current powering the LED 102 passes to zero during a period of extinction equal to T−αT, and the luminescence of the phosphorus 103 then drops progressively until it reaches a zero value during the duration of extinction of the LED 102.

Due to the fact that the duration “a”, or response time of the phosphorus 103, is short with respect to the duration αT, or lighting time of the LED 102, and that the period T is for example chosen higher than 20 Hz so that a person observing the light emitted by the LED 102 does not observe any twinkling, the light perceived by this person will normally correspond to a white light.

If the emitting layers of the active zone 120 of the LED 102 have structural defects that result for example in a shift, with respect to a target value, of the spectrum of the light emitted by the LED 102 towards the yellow colour, and/or that the operating conditions of the LED 102 result in such a shift of the spectrum of this light, this shift is detected by the detecting device 105. The values of the duty cycle α and/or of the period T are then modified by the intermediary of the control device 111 in order to reduce, during each one of the periods T, the duration during which the phosphorus 103 carries out the conversion of the blue light into a yellow light, i.e. reduce the ratio αT/a.

FIG. 5 shows the luminescence of the phosphorus 103 (bottom curve) obtained with a power current of the LED 102 (top curve) of which the values of the duty cycle α′ and of the period T′ were reduced with respect to the power signal of FIG. 4. In FIG. 5, the value of the period T′ is less than that of T and the value of the duty cycle α′ is chosen such that the duration α′T′, i.e. the lighting duration of the LED 102 during the period T′, is less than the response time of the phosphorus 103, i.e. the duration “a”. At instant tₒₙ corresponding to the instant when the value of the power signal passes from the zero value to a peak value Iₘₐₓ′, the luminescence of the phosphorus 103 increases progressively as in the case described hereinabove in relation with FIG. 4. However, due to the fact that the duration α′T′ is less than the duration “a”, the luminescence of the phosphorus 103 does not have the time to reach the maximum value L₁ and the maximum value of the luminescence reached here is equal to L₂ which is less than L₁. At the instant t_{off}, the value of the power current passes to zero and during the duration T′-α′T′, i.e. the duration of extinction of the LED 102, the luminescence of the phosphorus 103 then decreases progressively. It can be seen in FIG. 5 that the values of α′ and T′ are such that the luminescence of the phosphorus 103 do not have the time to return to a zero value and do not fall below a minimum value L₃ greater than 0.

In the case described in relation with FIG. 5, over a period T′ of the power signal, due to the fact that the duration α′T′ is less than the duration “a”, the proportion of the blue light converted into yellow light by the phosphorus 103 is not as substantial than in the case described in relation with FIG. 4. The average emission intensity of the phosphorus 103 is in this case lower in the case of FIG. 5 than in the case of FIG. 4. As such, the modification of the values of the duty cycle and of the period of the electric power signal makes it possible to offset the spectrum of the light emitted by the LED 102 towards the colour blue, as such offsetting the shift due to the structural defects of the LED 102 and/or of the operating conditions of the LED 102.

Modifying the duty cycle α and/or the period T of the electric power signal may modify the intensity of the light emitted by the LED 102. In order to offset this modification in the intensity of the light emitted, the peak value Iₘₐₓ of the electric power signal may be modified so that this light intensity is not affected by the change in the values of α and T. As such, if the detecting device 105 detects a light intensity that is too strong with respect to a target value of intensity, the control device 111 receiving as input the signal outputted by this detecting device 105 then orders the switched-mode electric power supply 110 to deliver the output current with a smaller peak value Iₘₐₓ or Uₘₐₓ. Inversely, if the detecting device 105 detects that the LED 102 is emitting a light with an intensity that is too low, the control device 111 then orders the switched-mode electric power supply 110 to deliver the output current with a larger peak value Iₘₐₓ or Uₘₐₓ. It is also possible to vary the intensity of the light emitted by the LED 102 by varying the period T of the power signal because for the same duty cycle, the light intensity obtained with a period T₁ will be greater than that obtained with a period T₂ when T₁<T₂.

Inversely to the example of adjusting the light spectrum described hereinabove, if the spectrum of the light emitted by the LED 102 tends towards the colour blue, it is possible to adjust the value of the duty cycle α and/or the value of the period T for example by increasing the value of αT with respect to the duration “a”, in order to increase, during each period T, the duration during which the luminescence of the phosphorus 103 is at its maximum, as such increasing the proportion of blue light converted into yellow light during the duration of each one of the periods T.

In general, the period T of the periodic electric power signal of the LED 102 is chosen sufficiently small so as not to observe any flickering or blinking of the LED 102, and that corresponds for example to a frequency between about 20 Hz and 1 MHz.

The example described hereinabove in relation with FIGS. 4 and 5 corresponds to the case where the power of the light emitted by the active zone 120 of the LED 102 is not sufficient to saturate the phosphorus 103 during the duration of lighting of the LED 102. The value of the period of the power signal is of the same order of magnitude as the response time of the phosphorus 103.

When the power of the light emitted by the active zone 120 of the LED 102 is sufficient to saturate the phosphorus 103 during the lighting duration of the LED 102, the parameters of the power signal are modified differently in order to modify the spectrum of the light emitted by the LED 102.

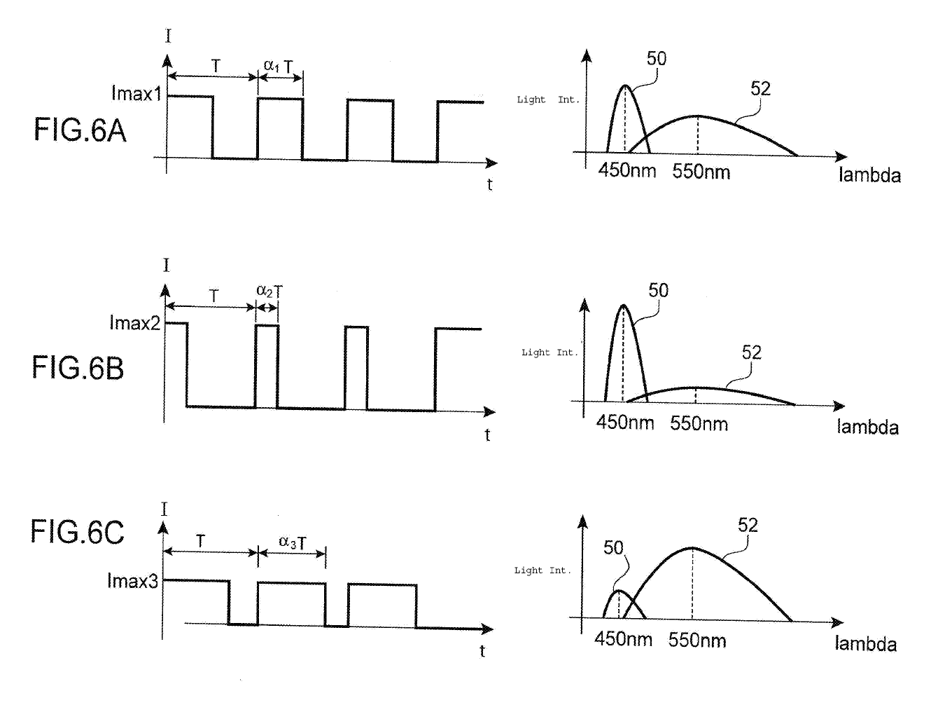

FIG. 6A shows a power current with a peak value Imax1, period T and duty cycle α1. The global spectrum of the light obtained with such a power current is also shown in FIG. 6A. The curve 50 represents the portion of the spectrum corresponding to the light coming from the active zone 120 of the LED 102 (blue light centred at λ=450 nm) which is not modified by the phosphorus 103 and the curve 52 represents the portion of the spectrum corresponding to the light emitted by the phosphorus 103 (yellow light centred at λ=550 nm).

When it is desired to reinforce the colour, for example blue, emitted by the active zone 120 of the LED 102 in the spectrum obtained, for example because the spectrum of the light emitted by the LED 102 tends towards the colour of the light emitted by the phosphorus 103, the peak value of the power signal is then increased (Imax2>Imax1) in order to increase the intensity of the blue light coming from the active zone 120 of the LED 102. Such a power signal is shown in FIG. 6B. It can be seen in FIG. 6B, which shows the light spectrum obtained with such a power signal of peak value Imax2, that the maximum value of the curve 50 is more substantial than that shown in FIG. 6A. So that this increase in the peak value of the power signal does not affect the average light power emitted by the LED 102, the value of the duty cycle of the power signal is reduced (α2<α1) in such a way that the LED 102 (therefore the active zone 120 and the phosphorus 103) is lit on the average a shorter period of time. Such a decrease in the value of the duty cycle therefore results in a decrease in the intensity of the light coming from the phosphorus 103 (the maximum value of the curve 52 shown in FIG. 6B is less than that shown in FIG. 6A). This decrease in the value of duty cycle also results in a decrease in the intensity of the light emitted by the active zone 120 (without this decrease in the value of the duty cycle, the maximum value of the curve 52 would be greater than that shown in FIG. 6B).

When it is desired to reinforce the contribution of the emission of the phosphorus in the spectrum obtained, for example because the spectrum tends towards the colour of the light emitted by the active zone 120, the peak value of the power signal is decreased (Imax3<Imax1) in order to decrease the intensity of the blue light coming from the active zone 120 of the LED 102. Such a power signal is shown in FIG. 6C.

It can be seen in FIG. 6C in particular that the maximum value of the curve 50 is lower than that shown in FIG. 6A. So that this drop in the peak value of the power signal does not affect the average light power emitted by the device, the value of the duty cycle of the power signal is increased (α3>α1) in such a way that the LED 102 is lit on the average longer. Such an increase in the value of the duty cycle results in an increase in the intensity of the light coming from the phosphorus 103 (the maximum value of the curve 52 shown in FIG. 6C is greater than that shown in FIG. 6A).

This increase in the value of duty cycle also results in an increase in the intensity of the light emitted by the active zone 120 (without this increase in the value of the duty cycle, the maximum value of the curve 50 would be greater than that shown in FIG. 6C).

The LED 102 described hereinabove can be made in the form of a planar diode, i.e. in the form of a stack of layers formed for example by epitaxial growth on a substrate, with the main faces of the various layers being arranged in parallel to the plane of the substrate (parallel to the plane (X,Y)). Alternatively, the LED 102 may also be made in the form of a nanowire.

According to another embodiment, the device 100 described hereinabove may not be intended to carry out a light emission, and correspond to a device for adjusting the spectrum and an intensity of a light intended to be emitted by a LED. Such a device for adjusting can for example be used to test LEDs in order to determine, for each one of these LEDs, the values of the period of the duty cycle and of the peak value of the electric power signal making it possible to obtain an emission of light for which the spectrum and the intensity correspond to the target values sought.

In this case, the device 100 may comprise a location (not shown) that makes it possible to temporarily connect the tested LEDs.

1-11. (canceled)

12: A light-emitting device comprising:
a light-emitting diode comprising an active zone coupled to phosphorus;
a detector of a spectrum and of an intensity of a light to be emitted by the light-emitting diode;
a switched-mode electric power supply configured to electrically power the light-emitting diode with a periodic signal with a duty cycle α such that αε]0;1],
a controller of the switched-mode electric power supply which can alter at least one of a peak value, a period, and the duty cycle α of the periodic signal according to the spectrum and intensity of the light to be detected and according to target values of the spectrum and of the intensity, and such that:
wherein when a light emitted by the active zone is of a power less than that making it possible to saturate the phosphorus, the controller carries out an adjustment of at least one of a value of the period and a value of the duty cycle of the periodic signal according to the spectrum of the light detected and according to the target value of the spectrum, and carries out an adjustment of at least one of the value of the duty cycle and a peak value of the periodic signal according to the intensity of the light detected and according to the target value of the intensity, and/or
wherein when a light emitted by the active zone is of a power greater than or equal to that making it possible to saturate the phosphorus, the controller carries out an adjustment of the peak value of the period signal according to the spectrum of the light detected and according to the target value of the spectrum, and carries out an adjustment of at least one of the value of the duty cycle and the period of the periodic signal according to the intensity of the light detected and according to the target value of the intensity.

13: The light-emitting device according to claim 12, wherein the active zone of the light-emitting diode comprises one or plural emitting layers each one that can form a quantum well.

14: The light-emitting device according to claim 13, wherein the one or plural emitting layers comprise InGaN.

15: The light-emitting device according to claim 13, wherein the light-emitting diode further comprises at least one n-doped semiconductor layer and at least one p-doped semiconductor layer between which are located the active zone.

16: The light-emitting device according to claim 14, wherein the detector comprises plural photodiodes optically coupled to the light-emitting diode and electrically connected to the controller.

17: The light-emitting device according to claim 14, wherein the periodic signal is a square signal.

18: The light-emitting device according to claim 14, wherein frequency of the periodic signal is between about 20 Hz and 1 MHz.

19: A device for adjusting a spectrum and an intensity of light to be emitted by a light-emitting diode comprising an active zone coupled to phosphorus, the device comprising:
a detector of the spectrum and of the intensity of the light to be emitted by the light-emitting diode;
a switched-mode electric power supply configured to electrically power the light-emitting diode with a periodic signal with a duty cycle α such that αε]0;1],
a controller of the switched-mode electric power supply which can alter at least one of a peak value, a period, and the duty cycle α of the periodic signal according to values of the spectrum and the intensity of the light to be detected and according to target values of the spectrum and of the intensity;
wherein when a light emitted by the active zone is of a power less than that making it possible to saturate the phosphorus, the controller carries out an adjustment of at least one of a value of the period and a value of the duty cycle of the periodic signal according to the spectrum of the light detected and according to the target value of the spectrum, and carries out an adjustment of at least one of the value of the duty cycle and a peak value of the periodic signal according to intensity of the light detected and according to the target value of the intensity, and/or
wherein when a light emitted by the active zone is of a power greater than or equal to that making it possible to saturate the phosphorus, the controller carries out an adjustment of the peak value of the period signal according to the spectrum of the light detected and according to the target value of the spectrum, and carries out an adjustment of at least one of the value of the duty cycle and the period of the periodic signal according to the intensity of the light detected and according to the target value of the intensity.

20: A method for adjusting a spectrum and an intensity of light to be emitted by a light-emitting diode including an active zone coupled to the phosphorus, the method comprising:
detecting a value of the spectrum and of the intensity of the light emitted by the light-emitting diode;
adjusting at least one of a period, a duty cycle α such as αε]0;1], and a peak value of a periodic signal electrically powering the light-emitting diode, according to the spectrum and the intensity of the light detected and according to target values of the spectrum and of the intensity;
iteratively repeating the detecting and adjusting until the spectrum and the intensity of the light detected correspond to the target values of the spectrum and of the intensity; and
wherein when a light emitted by the active zone is of a power less than that making it possible to saturate the phosphorus, the adjusting carries out an adjustment of at least one of a value of the period and of a value of the duty cycle of the periodic signal according to the spectrum of the light detected and according to the target value of the spectrum, and carries out an adjustment of the value of at least one of the duty cycle and of a peak value of the periodic signal according to intensity of the light detected and according to the target value of the intensity, and/or
wherein when a light emitted by the active zone is of a power greater than or equal to that making it possible to saturate the phosphorus, the adjusting carries out an adjustment of the peak value of the period signal according to the spectrum of the light detected and according to the target value of the spectrum, and carries out an adjustment of at least one of the value of the duty cycle and of the period of the periodic signal according to the intensity of the light detected and according to the target value of the intensity.
